(19) United States
(12) Patent Application Publication
(10) Pub. No.: US 2025/0218463 A1
(43) Pub. Date: Jul. 3, 2025

(54) Book with Audio Output and Recording Function

(71) Applicant: JAST Gifts Shenzhen Company Limited, Shenzhen City (CN)

(72) Inventor: Jen-Lin Chen, Cupertino, CA (US)

(21) Appl. No.: 18/776,199

(22) Filed: Jul. 17, 2024

(30) Foreign Application Priority Data
Dec. 28, 2023 (DE) 10 2023 136 771.4

(51) Int. Cl. G11B 20/10; G06F 3/16; H04R 1/02

(52) U.S. Cl. CPC G11B 20/10527; G06F 3/165; H04R 1/028; G11B 2020/10546; H04R 2499/11

(57) ABSTRACT

A book assembly with internal electronics. The book assembly has the structure of a book with a front cover, a rear cover, and at least one page. A plurality of touch sensors are disposed within the book with at least some of the pages containing a touch sensor. A microphone and speaker are supported by the book assembly and are usable with the book assembly being either open or closed. The book assembly contains circuitry for recording and storing custom audio files made via the microphone. The circuity can also hold preset audio files that come with the book assembly. At least one control switch is accessible on the book structure for selecting between a recording mode and a play mode. In the recording mode, the circuitry records a custom audio file for each of said plurality of touch sensors. The custom audio recording is assigned to the touch sensor that is activated at the time of the recording. After the recording, the circuitry plays the custom audio file assigned to a touch sensor when the touch sensor is activated. In alternate operational modes, the activation sensors can trigger the play of preset audio files when activated.

### BACKGROUND OF THE INVENTION

### 1. Field Of The Invention

The invention relates to a book with an audio output and a recording function. In particular, the invention relates to a book that has a digital recording and an audio output function that can be intuitively operated by means of sensors.

### 2. Prior Art Description

Books in which a digital audio output function is integrated are known in the prior art. Likewise, there are books known to have a recording function in addition to the audio output. Thereby, the output of an audio file or the recording of an audio file is usually triggered by pressing a sensor, wherein each sensor is assigned a specific memory size.

When a new audio file is recorded, the file originally found in the memory location is overwritten. If a larger memory space is required for a specific recording than is allocated to the corresponding sensor, the recording is ended when the maximum memory capacity allocated to such sensor is reached, although the memory spaces allocated to the other sensors may still have capacity available.

A disadvantage of the known audio books with recording function is, on one hand, that the built-in memory is not flexibly available. On the other hand, the number of audio files is limited to the extent that the originally intended recording is overwritten by a new audio recording and is subsequently no longer available.

In addition, the operation of such an audio book should be affected as intuitively as possible and the recording method should be as simple as possible.

It is therefore the object of the invention to provide a book with an audio output and a recording function that enables variable memory allocation and with which, in addition, an existing audio recording is not overwritten by the recording function.

Furthermore, it is the object of the invention to provide a book with an audio output and a recording function, which enables intuitive operation of the audio book through particularly simple operability, in particular for creating audio recordings.

These objects are achieved by a device with the features of claim 1. Advantageous embodiments are the subject matter of the dependent claims. It should be noted that the features listed individually in the claims can also be combined with one another in any technologically expedient manner and thus demonstrate further embodiments of the invention.

### SUMMARY OF THE INVENTION

The present invention is a book assembly with internal electronics. The book assembly has the structure of a book with a front cover, a rear cover, and at least one page. A plurality of touch sensors is disposed within the book with at least some of the pages containing a touch sensor. A microphone and speaker are supported by the book assembly and are usable with the book assembly being either open or closed.

The book assembly contains circuitry for recording and storing custom audio files made via the microphone. The circuity can also hold preset audio files that come with the book assembly. At least one control switch is accessible on the book structure for selecting between a recording mode and a play mode. In the recording mode, the circuitry records a custom audio file for each of said plurality of touch sensors. The custom audio recording is assigned to the touch sensor that is activated at the time of the recording. After the recording, the circuitry plays the custom audio file assigned to a touch sensor when the touch sensor is activated. In alternate operational modes, the activation sensors can trigger the play of preset audio files when activated.

### BRIEF DESCRIPTION OF THE DRAWINGS

For a better understanding of the present invention, reference is made to the following description of an exemplary embodiment thereof, considered in conjunction with the accompanying drawings, in which:

FIG. 1 is schematic view of the front side of an exemplary book assembly;

FIG. 2 is a rear view of the embodiment of FIG. 1;

FIG. 3 shows an inside view of the exemplary embodiment with the electronics arranged therein;

FIG. 4 is a schematic view of the book according to the invention in a partially opened state;

FIG. 5 shows an open page of the exemplary embodiment book according to the invention; and

FIG. 6 shows charts that outline the management of the dynamic memory.

### DETAILED DESCRIPTION OF THE DRAWINGS

Although the present invention book assembly can be embodied in many ways, only one exemplary embodiment is illustrated. The exemplary embodiment is being shown for the purposes of explanation and description. The exemplary embodiment is selected in order to set forth one of the best modes contemplated for the invention. The illustrated embodiment, however, is merely exemplary and should not be considered a limitation when interpreting the scope of the appended claims.

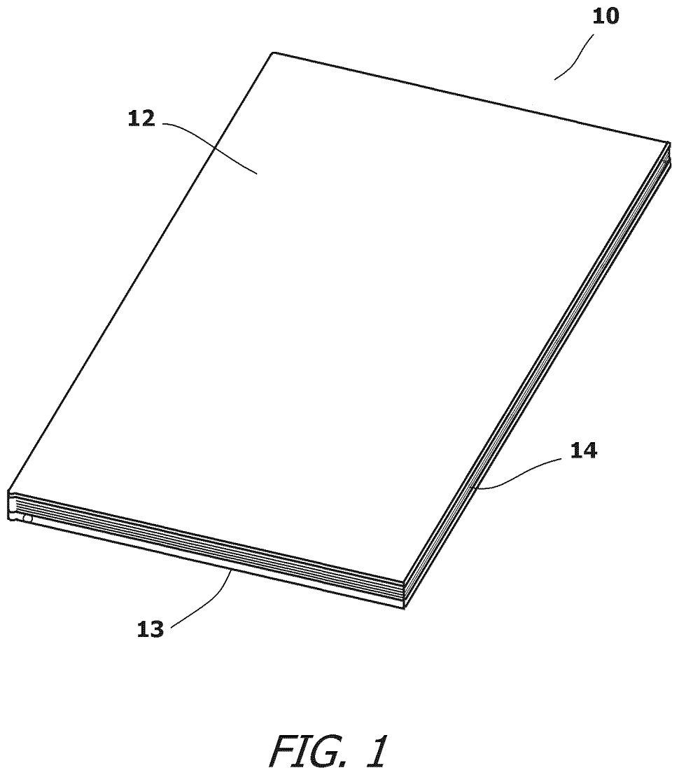

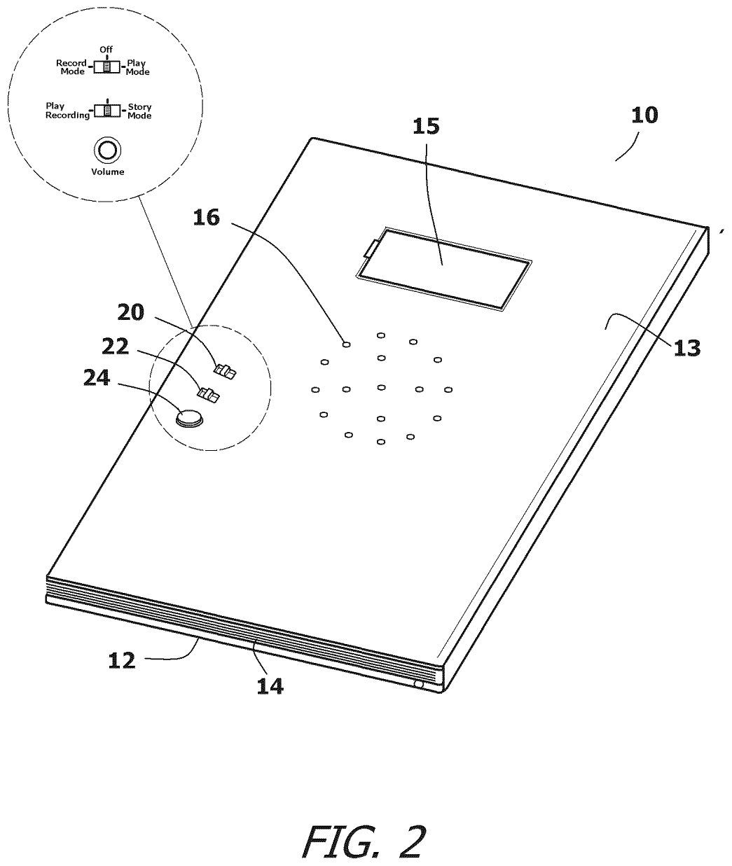

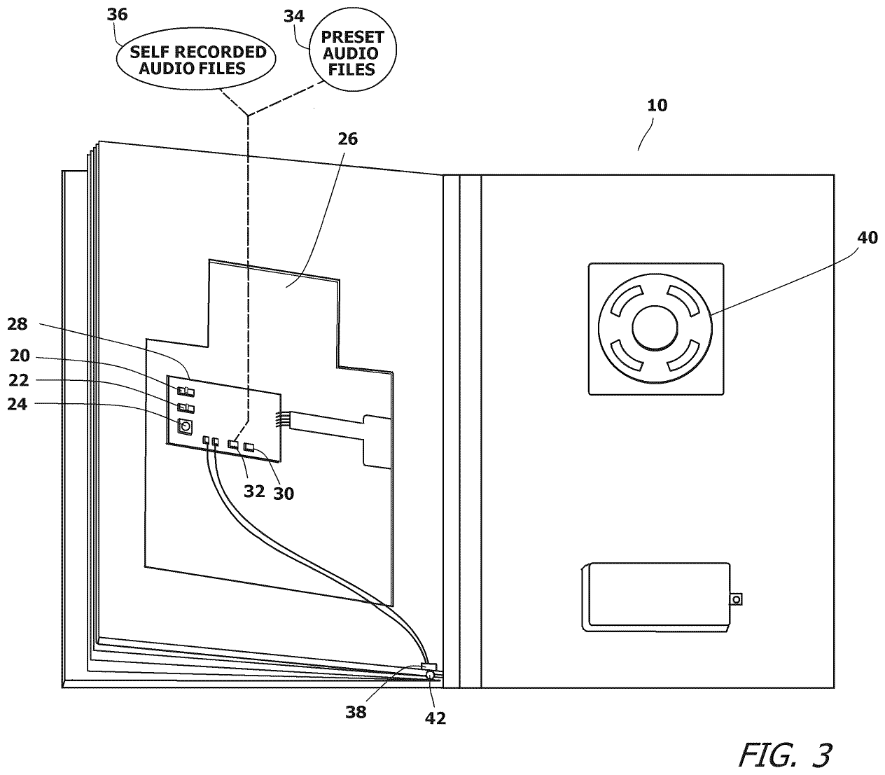

Referring to FIG. 1, FIG. 2 and FIG. 3, a book assembly 10 is shown that contains a front cover 12, a rear cover 13 and at least one book page 14. The front cover 12 is a traditional cover and may contain the graphics and title of a book. The rear cover 13 contains a battery compartment 15 and audio output openings 16 that lead to an internal speaker. In this manner, when the internal speaker is activated, the sound can be heard outside of the book assembly 10 regardless of whether the book assembly 10 is opened or closed. The rear cover 13 also contains access openings that provide access to a first control switch 20, a second control switch 22 and a volume control 24.

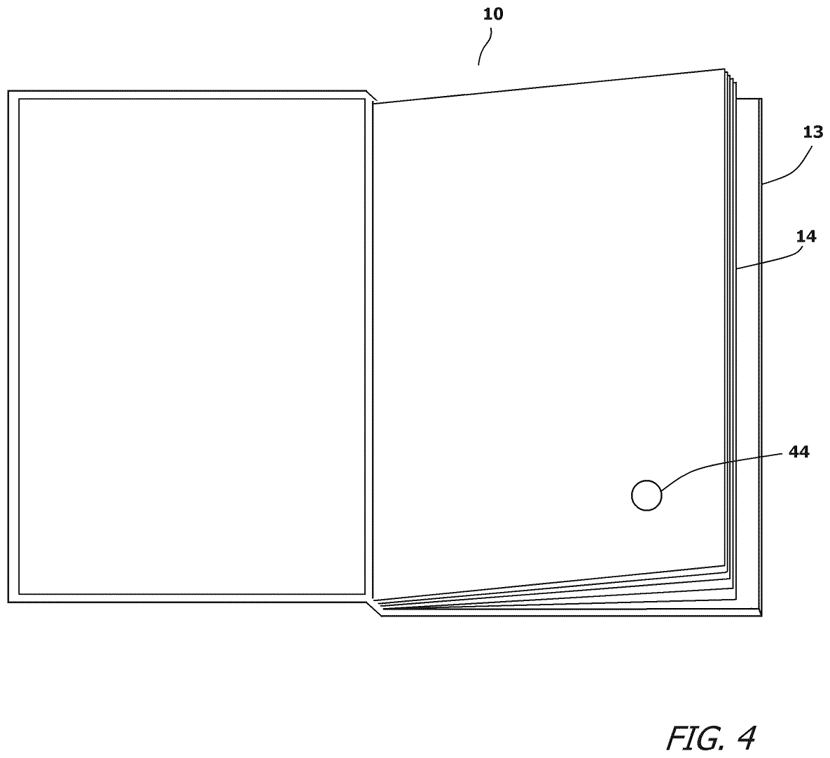

Referring to FIG. 3 in conjunction with FIG. 4, it can be seen that there is a hidden compartment 26 formed between the last page of the book assembly 10 and the rear cover 13 of the book assembly 10. The compartment 26 holds various electronic components. A circuit board 28 is mounted in the compartment 26. The circuit board 28 contains a microprocessor 30 and memory circuitry 32. The memory circuitry 32 includes a read-only memory and a random access memory. The read-only memory contains audio files that are prerecorded. These can include the recorded sound of a person reading the book, music, tones, noises, or the like, and are herein referred to as preset audio files 34. The random access memory is capable of actively recording and storing audio sounds, such as a person reading the book aloud, which are herein referred to as self-recorded audio files 36.

Leads also extend from the circuit board 28 that extend to a microphone 38 and a speaker 40. The speaker 40 is aligned with the audio output openings 16 in the rear cover 13. The microphone 38 is positioned adjacent an opening 42 at the bottom of the compartment 26. In this manner, the microphone 38 is accessible regardless of the number of open or closed pages 14 in the book assembly 10.

At least one touch sensor 44 is provided on at least some of the pages 14 of the book assembly 10. The touch sensors 44 are suitable for detecting the pressure on a specific region of a book page 14. The touch sensors 44 are capacitive pressure and/or touch sensors. Within the meaning of the invention, the terms “touch sensor” and “pressure sensor” are used synonymously for such sensors. Here, it is particularly relevant that the touch sensor 44 is suitable for detecting a specific pressure or a specific touch of the user. In this respect, the terms “pressure” and “touch” along with “press” and “touch” are considered equivalent within the meaning of the invention. Here, it is only important that the corresponding touch sensor 44 can be triggered by a corresponding action.

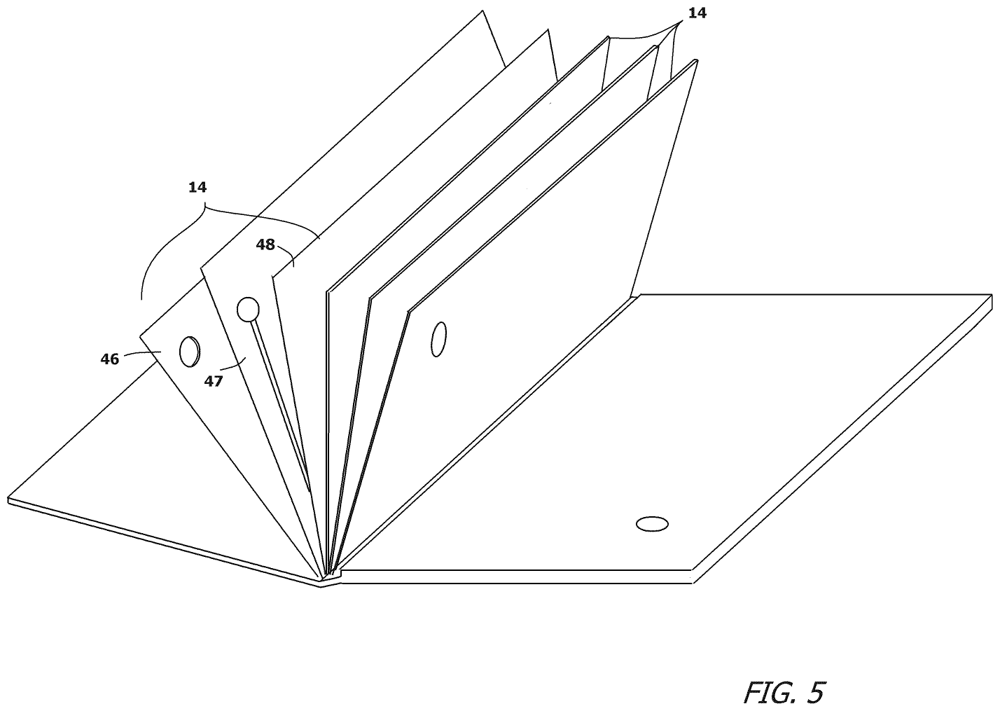

Optionally, the book assembly 10 can also include LED lights that are arranged in parts of the book assembly 10, i.e., in the book pages 14 and in at least one of the book covers 12, 13 or the book spine. Referring to FIG. 5 it can be seen that in a book page 14 or a book cover 12, 13 the corresponding book page 14 or cover 12, 13 preferably comprises three laminated layers 46, 47, 48. The first layer 46 corresponds to the front side of the book page 14 or book cover 12, 13 and the third layer 48 corresponds to the back side of the book page 14 or book cover 12, 13. The second or middle layer 47 is preferably interposed between the first layer 46 and third layer 48. The middle layer 47 contains the electronics, with recesses for the electronics to be embedded. The size of the recesses and the thickness of the material of the second layer 47 are to be selected appropriately depending on the electronic components to be embedded. If the electronic components to be embedded are only very thin, such as the touch sensors 44 arranged in the pages 14, then the second layer 47 can also consist only of the corresponding electronics.

Referring to FIG. 2 in conjunction with FIG. 5, it will be understood that two control, switches 20, 22 are provided. In the preferred embodiment, the first control switch 20 has three settings that correspond to three operating modes. Preferably, the three operating modes that can be selected include “Record Mode,” “Play Mode,” and “Off”. The first control switch 20 is therefore used to select if the book assembly 10 is being used to create a recording or play a recording. The second control switch 22 has two operating modes, which include “Play Recording” and “Story Mode.”

The electronics are activated when one of the touch sensors 44 contained within the book assembly 10 are triggered. The action that occurs when a touch sensor 44 is triggered depends upon the selections made for the first control switch 20 and the second control switch 22. In a first mode of operation, the first control switch 20 is positioned to the “Play Mode” setting and the second control switch 22 is set to the “Story Mode” setting. In this mode, the book assembly 10 plays back one of the preset audio files 34 when a touch sensor 44 is activated. In this manner, a page 14 of the book assembly 10 can be read aloud, or sound effects can be generated that complement the story set forth in the book assembly 10.

A second unique mode of operation occurs when the first control switch 20 is positioned to the “Record Mode” setting. In this mode, one self-recorded audio file 36 can be recorded for each touch sensor 44. This means that a separate and distinct audio recording can be created for each of the touch sensors 44. To record a self-recorded audio file 36 for any one touch sensor 44, the touch sensor 44 is pressed and held until the recording has ended. Thus, recording of the self-recorded audio file 36 lasts as long as the corresponding touch sensor 44 is pressed.

Alternatively, it can also be provided that the recording is started by a first press on the corresponding touch sensor 44 and ended by a second press.

After the recording has ended, the self-recorded audio file 36 is automatically played back once for checking purposes. If the audio recording is to be re-recorded, the above steps can be repeated as often as required. After the audio recording for each of the touch sensors 44 has ended, the first control switch 20 can be moved to the “Off” position.

In a third mode of operation, the first control switch 20 is set to its “Play Mode” position and the second control switch 22 is set to its “Play Recording” position. In this mode, the self-recorded audio file 36 recorded for any of the touch sensor 44 will play when that touch sensor 44 is activated. As such, a customized audio playback is provided for each of the touch sensors 44. The self-recorded audio files 36 are stored in the random access memory of the memory circuity 32. The total memory space available for self-recorded audio files 36 is dynamically distributed to the various touch sensors 44. In this manner, a flexible memory capacity is available for the self-recorded audio files 36. This enables the memory circuitry to allocate a specific memory space for storing the self-recorded audio files 36. The self-recorded audio files 36 are permanently assigned to different touch sensors 44, but the self-recorded audio files 36 are not limited in size. Rather, the entire available memory is available to each self-recorded audio file 36 and therefore it can also be said that the remaining memory capacity can be dynamically allocated to each touch sensor 44. A minimum memory can be reserved for each touch sensor 44 during the dynamic allocation of memory capacity, so that at least a brief audio recording is initially possible for each touch sensor 44. The book assembly 10 therefore has the advantage over the prior art in that it enables improved utilization of the installed memory, in particular due to the dynamic memory allocation. Thus, the recording of comparatively longer audio files 36 is also possible with an overall limited storage capacity. In addition, the option of managing pre-installed audio files and self-recorded audio files 36 prevents the disadvantage of known books having to overwrite the original audio file with self-recorded recordings.

It will therefore be understood that in a preferred embodiment, the electronics of the book assembly 10 contains two switches 20, 22. Two operating modes can be selected with the first switch 20, namely “Record Mode” and “Play Mode.” In the “Record Mode” custom self-recorded audio files 36 can be created stored for each of the touch sensors 44. In the alternate “Play Mode,” the book assembly will play either the preset audio files 34 or the self-recorded audio files 36 when a touch sensor 44 is activated, depending upon the setting of the second switch 22.

The second switch 22 can be used to select which audio files are to be played, namely either the preset audio files 34 or the self-recorded audio files 36. When the “Play Recording” setting is selected, the book assembly 10 will play the self-recorded audio files 36 when a touch sensor 44 is activated. Conversely, When the “Play Story” setting is selected, the book assembly 10 will play the preset audio files 34 when a touch sensor 44 is activated.

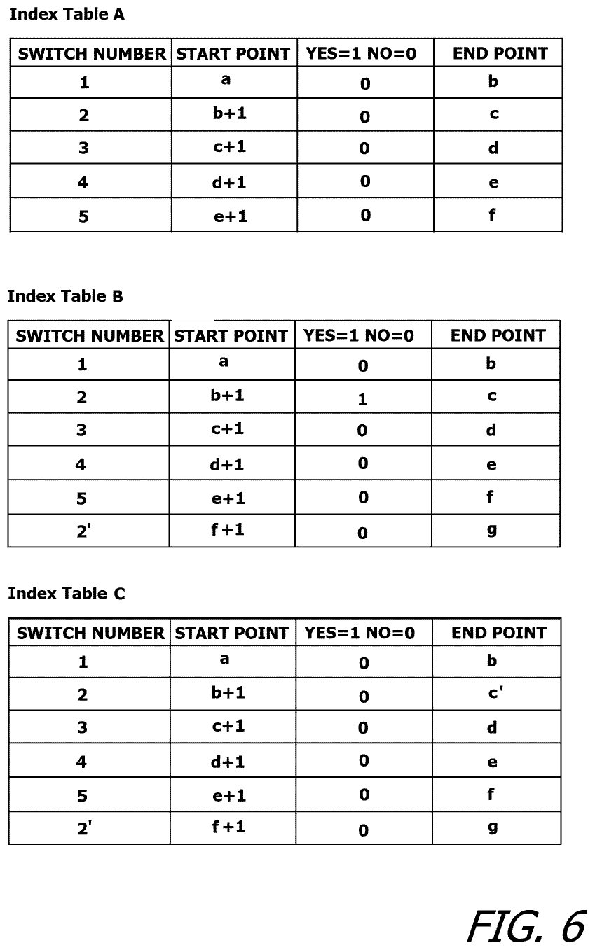

In FIG. 6, an index table is provided for dynamic memory management, in which the start point and the end point of the respective audio recording are stored. Referring to FIG. 6 in conjunction with FIG. 3, it will be understood that when a touch sensor 44 is pressed, the microprocessor 30 recognizes which touch sensor 44 was pressed and searches the index table to retrieve the corresponding audio file from the memory circuitry 32 and plays it back. As is indicated in FIG. 6, the state of the memory is dependent upon the initial self-creation of audio files. By way of example, for a book with five pages, each page is assigned a memory location with a start point (a, b+1, c+1, d+1, e+1, etc.) and an end point (b, c, d, e, f, etc.). In addition, for each memory slot, it is noted whether it is partitioned or not (YES=1; NO=0). Based on the index table, the state of the memory after the re-recording of one or more audio files, wherein, by way of example, new audio recording 2′ (2) for page 2 is longer than originally recorded audio file 2. In such a case, more storage space is required for the audio file and the file must be partitioned.

The partition index changes accordingly from “0” to “1”. As is indicated by section B of FIG. 6, the new audio recording 2 for page 2 is longer than the original recorded audio file 2, so the new recording will start at b+1, and temporarily end at c to fully re-utilize the original memory space, mark partition to 1, to find the next available memory space, marked 2′, continued from f+1 to end g. The next available memory space g+1 is stored and saved.

As is indicated by section C of FIG. 6, the state of the memory after re-recording one or more audio files, wherein, by way of example, a new audio recording 2 for page 2′ (2) is shorter than the previously recorded audio file 2′ (2). In such a case, less storage space is required for the audio file and the file no longer must be partitioned. Accordingly, the partition index of new recording 2 changes again from “1” to “0,” and only a new end point c′ is assigned. Also, the index table 2′ (f+1, g) is cleaned. Any memory space still available between points c′ (c′+1) and c can be used for other audio files. A defragmentation program can regroup the memory at regular intervals as it progresses to eliminate partitions. After defragmentation, the index table will become as shown in section A of FIG. 6.

Referring to all figures, it will be understood that the book assembly 10 can be configured to play preset audio files 34 when a touch sensor 44 is activated. However, using the same touch sensors 44, customized recordings can also be recorded and played. To create a self-recorded audio file, the following steps are utilized.

(A) Selection of the operating mode for recording self-recorded audio files 36 using the corresponding control switches 20, 22;

(B) Opening of the book page 14 for which a self-recorded audio files 36 is to be created;

(C) Activation of the touch sensor 44 on the book page 14 for which a self-recorded audio files 36 is to be created;

(D) Recording of the self-recorded audio files 36;

(E) Optional listening to the self-recorded audio files 36 after the recording has ended;

(F) Optional repetition of steps (A) through (E) for the same or additional pages or sensors.

Once the self-recorded audio files 36 are recorded, those recordings are assigned to the touch sensors 44 and specific files are played when specific touch sensors 44 are activated.

It will be understood that the embodiment of the present invention that is illustrated and described is merely exemplary and that a person skilled in the art can make many variations to that embodiment. For instance, an interface can be provided for wireless or wired data exchange of audio files with external devices such as computers, smartphones, laptops, and tablets. It is also conceivable that specific audio files are played automatically when the book assembly is opened and other audio files are only played when a sensor is pressed. All such embodiments are intended to be included within the scope of the present invention as defined by the claims.

1. An assembly, comprising:
a book structure that includes a front cover, a rear cover and a plurality of pages disposed between said front cover and said rear cover, wherein said plurality of pages includes a last page and a compartment is formed between said last page and the rear cover;
a plurality of touch sensors wherein at least some of said plurality of pages contain at least one of said plurality of touch sensors;
a microphone supported by said book structure within said compartment;
a speaker supported by said book structure within said compartment;
circuitry for recording and storing audio files made from audio signals received through said microphone, wherein said circuitry is supported by said book structure within said compartment;
at least one control switch accessible on said rear cover for selecting between a recording mode and a play mode, wherein said circuitry records one of said audio files for each of said plurality of touch sensors when in said recording mode, wherein said circuitry records one of said audio files for each of said plurality of touch sensors as each of said plurality of touch sensors is activated in said recording mode; and
wherein said circuitry plays one of said audio files recorded when in said play mode and when any one of said plurality of touch sensors is activated.

2. The assembly according to claim 1, wherein said circuitry includes a dynamic memory for storing said audio files, wherein said dynamic memory has a memory capacity that can be dynamically distributed to recordings made using all of said plurality of touch sensors.

3. The assembly according to claim 1, further including a read-only memory that contains preset audio files not recorded through said microphone.

4. The assembly according to claim 1, wherein said at least one control switch contains a setting that enables said circuitry to play one of said preset audio files each time one of said plurality of touch sensors is activated.

5. The assembly according to claim 1, wherein said touch sensors are capacitive pressure sensors.

6. The assembly according to claim 1, further including a volume control accessible on said book structure.

7. (canceled)

8. An assembly, comprising:
a book structure that contains a plurality of pages disposed between a front cover and a rear cover, wherein said book structure has at least one compartment between a last of said plurality of pages and said rear cover;
a plurality of touch sensors disposed on said plurality of pages;
circuitry disposed within said compartment that can record and store a custom audio file for each of said plurality of touch sensors, wherein said custom audio file is played when each of said plurality of touch sensors is activated.

9. The assembly according to claim 8, wherein said circuitry includes a dynamic memory for storing each said custom audio file, wherein said dynamic memory has a memory capacity that can be dynamically shared by each said custom audio file.

10. The assembly according to claim 8, further including a read-only memory that contains preset audio files not custom recorded.

11. The assembly according to claim 8, further including control switches for selecting operational modes, wherein in a first operational mode, said preset audio files are played and in a second operational mode each said custom audio file is played.
